(19) United States
(12) Patent Application Publication
(10) Pub. No.: US 2008/0296149 A1
(43) Pub. Date: Dec. 4, 2008

(54) MIXED CHROMIUM OXIDE-CHROMIUM METAL SPUTTERING TARGET

(76) Inventors: David E. Stevenson, Dexter, MI (US); Li Q. Zhou, Ann Arbor, MI (US)

Correspondence Address: ROBERT L. STEARNS;Dickinson Wright PLLC, Suite 2000, 38525 Woodward Avenue, Bloomfield Hills, MI, 48304-2970, US

(21) Appl. No.: 11/875,480

(22) Filed: Oct. 19, 2007

Related U.S. Application Data
(60) Provisional application No. 60/862,333, filed on Oct. 20, 2006.

(51) Int. Cl. C23C 14/34

(52) U.S. Cl. 204/192.15; 204/298.13; 264/293

(57) ABSTRACT

An AC or DC sputtering target for depositing thin films of chromium sub oxides on a substrate contains oxides of chromium, chromium metal and incorporated oxygen. The target has a resistivity of 200Ω·cm or less. The target can be made from a combination of oxides of chromium powder and chromium metal, such as in powder form, or can be made starting with 100% chromium oxide or sub oxide material that is subjected to a reducing atmosphere either before or during the process of making the target in order to reduce a fraction of the chromium oxide and/or sub oxide material to chromium metal and retained oxygen. Such a target can enable the sputtering process to be conducted using inert argon gas only to yield a thin film of chromium oxide. This enables the surface of the target to remain in a continuously stable condition and free of the arcing problems associated with using chromium targets and argon and oxygen gas.

This application claims priority to U.S. Provisional Application Ser. No. 60/862,333, filed Oct. 20, 2006.

### BACKGROUND OF THE INVENTION

This invention relates generally to sputtering targets, and particularly chromium oxide sputtering targets, and to methods of making such targets.

Thin films of chromium oxide and sub oxide are an important material for a wide variety of optical and electrical applications. Many integrated circuit, flat panel display and optical devices require thin films of chromium oxide of sub oxide.

One of the principal methods for producing chromium oxide thin films is magnetron sputtering deposition. The existing commercial sputtering process for such thin film deposition is commonly referred to as reactive DC or AC sputtering. In this process a DC or AC power source is connected to a planar or rotary magnetron cathode. A chromium metal sputtering target is attached to the side of the magnetron cathode that is located in a vacuum chamber. A mixture of argon and oxygen gas is introduced into the vacuum chamber at the same time that a DC or AC current is applied to the magnetron cathode. This results in the formation of ionized plasma near the surface of the chromium sputtering target. The positive ions of argon and oxygen in the plasma are attracted to the target with high kinetic energy. These ionized gas atoms or molecules bombard the sputtering target with sufficient force to ‘sputter’ off the surface of the target atoms of the chromium metal. To form thin films of chromium oxide or sub oxide on a substrate material, such material is transported or positioned in front of the target as this sputtering process is occurring. A substantial fraction of the ionized oxygen that bombards the sputtering target reacts with the chromium metal on the surface of the target to form a few atomic layers of chromium oxide or sub oxide on the target surface. As the target surface undergoes continuous bombardment by both argon and oxygen both chromium and oxygen are sputtered from the surface of the target. Some of the sputtered oxygen is re-ionized and returned to the target surface. The remainder of the sputtered oxygen is either deposited on the surface of the substrate or evacuated from the vacuum chamber by the high vacuum pumps. At the surface of the substrate the arriving chromium and oxygen combine to form a chromium oxide or sub oxide thin film.

This process has many limitations and problems. The primary limitation is the non-stable condition of the chromium target during the deposition process. When planar chromium sputtering targets are used, the region outside of the ‘racetrack’ erosion zone of the target surface becomes coated with an insulating film of CrOx. This creates a capacitor like condition on the surface of this insulating CrOx film. When this insulating film becomes thick enough to form an effective dielectric barrier, an electrical charge of a high potential accumulates on this insulating surface. When the voltage of such charge becomes sufficiently large, an arc discharge occurs between the surface of the insulating film and the ‘clean’ metallic area of the chromium sputtering target. Under some conditions, this arc discharge can also occur between the surface of the insulating film and the substrate to be coated or to a nearby surface inside the vacuum chamber. Reactive sputtering processes require high amounts of oxygen gas flow to enable chromium oxide or sub oxide thin films to be deposited. The oxidation of the sputtering target that results from these high flows of oxygen not only causes arcing but also contribute to many other forms of process instability.

### SUMMARY OF THE INVENTION

The invention provides a means of incorporating oxygen in the chromium target while at the same time achieving sufficient electrical conductivity in the target to enable it to be sputtered using a DC or AC power source. Such a target can enable the sputtering process to be conducted using inert argon gas only. This enables the surface of the target to remain in a continuously stable condition and free of the arcing problems associated with using chromium targets and argon and oxygen gas.

According to one aspect of the invention a sputtering target material composition comprises a combination of oxides of chromium and chromium metal. The composition can contain between 50% to 85% by weight of oxides of chromium and 15% to 50% by weight chromium metal. The composite material is prepared using any one of several processes such as hot isostatic pressing, sintering, casting etc. to create a bulk solid material that has a resistivity of 200Ω·cm or less. It is also possible to create such a sputtering target using 100% chromium oxide or sub oxide material that is treated in a reducing atmosphere prior to or during the target material compaction, densification, casting or other forming process to create a composition that is electrically conductive but still has significant fractions of oxygen in the composition. Regardless of the method of fabrication, the conductivity of the material needs to be sufficient to allow such material to be utilized as a sputtering target for DC or AC magnetron or diode sputtering of thin films. The chromium oxide stoichiometry of the thin films sputtered from such targets can be varied as a function of the oxygen fraction in the target material.

### DETAILED DESCRIPTION

In an exemplary embodiment, the target composition will contain between about 50% to 85% by weight chromium oxide and about 15% to 50% by weight chromium, each of which is in powder form. These powders are blended and milled together in a plastic or ceramic container using zirconia balls as milling media until the particle size of the powder is less than 5 um.

Once the mixed powder has been sufficiently blended and milled, the blended powder base is placed in a metal can made from Nb metal. The powder mixture is heated in a vacuum chamber until the residual moisture and atmospheric gas is removed and the metal can is hermetically sealed.

The sealed can is subjected to predetermined pressure and heat levels such that a dense target can be achieved. As used herein, “dense” refers to a density of more than 90% of theoretical density. In a preferred embodiment, the pressure is more than 20,000 PSI and a temperature between 1350 to 1450° C.

In an exemplary embodiment, the metal can is placed inside a hot isostatic press. The sealed can is first heated to 1000° C. under vacuum. Then the gas pressure in the furnace is slowly raised to 20,000 PSI while simultaneously increasing the temperature heating to 1450° C. The metal can is subjected to the 20,000 PSI pressure and 1450° C. temperature for a period of approximately one hour. At the end of this one hour period the HIP the temperature and pressure in the HIP is reduced to atmospheric pressure and room temperature over a period of two hours.

The sintered material that is formed in this process has a resistivity of less than 200Ω·cm. which makes it suitable for DC or AC sputtering.

Although only one method of preparing chromium oxide-chromium target is described here, the invention contemplates that various manufacturing methods can be used to prepare the target that yield the same desirable characteristics as prepared by hot isostatic pressing described above. Such additional processes include hot pressing in an inert gas or vacuum atmosphere, inert gas sintering, casting, plasma spraying, laser sintering, explosion forming and many other commercial metal and ceramic forming processes.

Some features and advantages of the invention include:

1. By controlling the oxygen fraction in the target, it is possible to deposit various chromium sub oxide thin films using only inert Ar as the sputtering gas.

2. Unlike reactive sputtering, virtually all of the chromium and oxygen arriving at the substrates has uniform arrival energy. This promotes the formation of a smoother and more defect free thin film.

3. The large amount of uniformly dispersed oxygen in the target creates higher secondary electron emission from the surface of the target resulting in higher deposition rate and lower plasma impedance.

4. The conductive CrOx:Cr target enables improved process stability compared to conventional reactive deposition of CrOx films.

5. The raw materials used to fabricate CrOx:Cr targets have a lower cost than high purity chromium metal used for chromium metal sputtering targets.

6. By controlling the fabrication method, starting raw materials and oxidation state of the composition, it is possible to prevent dangerous chromium oxide compositions such as hexavalent chromium from being formed either in the target or in the sputtered thin films.

We claim:

1. A sputtering target suitable for AC or DC consisting essentially of a composition of oxides of chromium and chromium metal.

2. The sputtering target of claim 1, wherein the composition contains between 50% to 85% by weight oxides of chromium and 15% to 50% by weight chromium metal.

3. The sputtering target of claim 1 having a resistivity of 200Ω·cm or less.

4. A method of making a chromium oxide-chromium metal sputtering target, comprising:
treating 100% chromium oxide or sub oxide material in a reducing atmosphere to reduce a fraction of the material to chromium metal and retained oxygen before or during a forming process of the target.

5. The method of claim 4 wherein the oxygen is uniformly dispersed through the target.

6. The method of claim 5 wherein the resultant target is made to have a resistivity of 200Ω·cm or less.

7. The method of claim 4 wherein the forming process is a process selected from the group consisting of: hot isostatic pressing in an inert gas or vacuum atmosphere, inert gas sintering, casting, plasma spraying, laser sintering, or explosion forming.

8. A method of depositing chromium sub oxides thin films on a substrate comprising:
preparing a sputtering target containing oxides of chromium, chromium metal and oxygen and sputtering the target by AC or DC sputtering using only inert AR as the sputtering gas.

9. The method of claim 8 wherein the sputtering target is prepared to have a resistivity of 200Ω·cm or less.
